(19) United States
(12) Patent Application Publication
(10) Pub. No.: US 2012/0176762 A1
(43) Pub. Date: Jul. 12, 2012

(54) ELECTRONICS PATCH WITH ULTRA THIN ADHESIVE LAYER

(76) Inventors: Elizabeth L Hotaling, Piedmont, SC (US); Jay C. Sinnett, Greenville, SC (US)

(21) Appl. No.: 13/497,022

(22) PCT Filed: Sep. 30, 2009
(86) PCT No.: PCT/US09/59120

§ 371 Date: Mar. 19, 2012

(51) Int. Cl. H05K 7/02; B29C 65/48

(52) U.S. Cl. 361/807; 156/249

(57) ABSTRACT

An electronic patch comprising a patch body composed of a cured rubber composition and having an electronics component mounted thereto, the patch body comprising a bottom surface for bonding the electronics patch to an article. Also included is an adhesive layer of an uncured rubber composition applied to the patch bottom surface, wherein the adhesive layer is no more than 0.3 mm thick and is curable between 18° C. and 26° C. over 20 hours and 48 hours. A removable protective film may be applied to a bonding surface of the adhesive layer, wherein the protective film is removed prior to applying the patch to the article. A method is provided, including applying a vulcanizing agent to an interior surface of the tire and applying the electronics patch over the vulcanizing agent, wherein the protective film on the patch is removed prior to applying the electronics patch to the tire.

### BACKGROUND OF THE INVENTION

1. Field of the Invention

This invention relates generally to rubber based adhesives and more specifically, to rubber based adhesives for bonding patches having electronic sensors and/or transmitters to a rubber based article such as a tire.

2. Description of the Related Art

Electronics integrated within a tire or other product offer potential advantages such as asset tracking and measurement of physical parameters such as temperature, pressure, rotation, deflection and so forth. Many of these systems typically rely on a wireless data link to communicate with an information system outside of the vehicle. Such information systems may include, as non-limiting examples, on-board computer systems, drive-by interrogators, or hand-held interrogators. In addition, the types of data communicated over such wireless data links are wide and varied and include such as not only the previously mentioned temperature and pressure but also other physical parameters such as tire rotation speed as well as data corresponding to manufacturing data and a host of other information.

The type of electronics that may be incorporated into the tire includes many different types of sensors and/or transmitters and/or receivers. Many systems utilize, for example, radio frequency communication or wireless communication systems between the tire and an external monitoring or interrogating device. Such wireless communication systems often include an RFID tag for communication between an electrical device and the external monitoring or interrogating device.

Such electronics may be incorporated into the tire in many different ways, including by mounting the electronics on a rubber based patch and then bonding the patch to the tire or other article. Such a patch may be bonded to the interior of the tire or the exterior of the tire.

Such patches may be bonded to the tire using a layer of a rubber based adhesive that is curable at or near room temperature. Curing, or vulcanization, is a process that results in the crosslinking between the polymer chains of the rubber in the tire, the patch and the layer of rubber based adhesive, the crosslink typically formed by sulfur atoms or a chain of sulfur atoms. This curing process bonds the patch to the tire.

Through the rotation of the tire, severe stresses are placed on the patch bonded to the tire. The life of the patch may be shortened due to these stresses and the repetitive flexing of the tire/patch as the tire rotates: Research continues to determine ways to lengthen the life of these patches by improving their durability, especially their durability as it relates to the stresses and repetitive flexing of the tire/patch.

### SUMMARY OF THE INVENTION

Particular embodiments of the present invention include electronics patches and methods for their use. One embodiment provides an electronic patch comprising a patch body composed of a cured rubber composition and having an electronics component mounted thereto, the patch body comprising a bottom surface for bonding the electronics patch to an article. Also included is an adhesive layer composed of an uncured rubber composition and applied to the patch bottom surface, wherein the adhesive layer is no more than 0.3 mm thick and is curable at a selected temperature between 18° C. and 26° C. over a time period of between 20 hours and 48 hours. A removable protective film is further included, the film being applied to a bonding surface of the adhesive layer, wherein the protective film is removed prior to applying the electronics patch to the article.

Some embodiments provide that the uncured rubber composition of the adhesive layer comprises natural rubber in a majority amount and at least 10 phr of sulfur or alternatively, at least 6 phr of sulfur. It should be noted that as used herein, phr refers to parts per hundred parts of rubber by weight as commonly used in the industry.

Another embodiment provides a method for applying an electronics patch to a tire, the method comprising applying a vulcanizing agent to an interior surface of the tire and applying the electronics patch described above over the vulcanizing agent, wherein the protective film on the patch is removed prior to applying the electronics patch to the tire.

The foregoing and other objects, features and advantages of the invention will be apparent from the following more detailed descriptions of particular embodiments of the invention, as illustrated in the accompanying drawing wherein like reference numbers represent like parts of the invention.

### BRIEF DESCRIPTION OF THE DRAWINGS

FIG. 1 is a cross sectional view of an exemplary electronics patch having a very thin adhesive layer for bonding the patch to an article.

FIG. 2 is a perspective view of a tire having an electronics patch bonded to the tire.

FIG. 3 is a schematic of a process for producing a very thin adhesive layer on a plastic film.

### DETAILED DESCRIPTION OF PARTICULAR EMBODIMENTS

Reference will now be made in detail to embodiments of the invention, one or more examples of which are illustrated in the drawings. Each example is provided by way of explanation of the invention. For example, features illustrated or described as part of one embodiment can be used with another embodiment to yield still a third embodiment. It is intended that the present invention include these and other modifications and variations.

Particular embodiments of the present invention include electronic patches and methods for applying such patches to an article, such as a tire. An electronics patch is an assembly made of a rubber composition having one or more electronics components mounted thereto. The electronics components may be mounted on a surface of the patch or may be partially or totally embedded in the patch. A nonexhaustive list of electronics components that may be mounted on and/or within an electronics patch may include, for example, an RFID tag, temperature sensor, pressure sensor, accelerometer, battery or other power source and/or antennae with a signal receiver, transmitter or both.

The patches that are embodiments of the present invention are those that can be bonded to an article without curing at high temperatures. As such, the patches are composed of a cured rubber composition and the article to which they are applied typically is either composed of a rubber composition or has a surface to which the patch is applied that is composed of a rubber composition. A very thin adhesive layer, composed of an uncured rubber composition and no more than 0.3 mm thick, is applied to the patch for bonding the patch to the article. Alternatively, the adhesive layer may no more than 0.25 mm thick or no more than 0.2 mm thick. In particular embodiments, in conjunction with the maximum thicknesses mentioned above, the very thin adhesive layer may be at least 0.1 mm thick.

An advantage of using the very thin layer of adhesive material is that there is less migration of materials that are a part of the adhesive rubber composition into the material of the patch. Chemicals, such as sulfur, that are added to the adhesive rubber composition in quantities sufficient to allow curing of the adhesive material at a low temperature migrate from the adhesive material into the patch material over time. Such migration can cause degradation of the patch material and cause the patch crack or otherwise degrade, causing the patch to lose its bond to the article, such as a tire.

This phenomenon may be enhanced when the patch is applied to an inner liner of a tire, which is typically high in butyl rubber content, the butyl rubber being a barrier to such chemical migration. While in other applications the chemicals can migrate more freely in both directions (towards the patch and towards in the article to which it is bonded), if the patch is bonded to a material that blocks such migration, such as butyl rubber, then the migration towards the patch is enhanced.

A suitable material for the adhesive layer is one composed of an uncured rubber composition that may be cured at a selected curing temperature of between 18° C. and 26° C. over a time period of between 20 hours and 48 hours. Several such products are available on the market, one of which is Chemical Cure Gum #760 available from Tech International with offices in Johnstown, Ohio. This product is available in rolls with the adhesive material applied to a removable plastic protective film. However, these materials are not available in a thickness that is as thin as contemplated in the embodiments of the invention disclosed herein. Instead, the materials must be further processed to make them of a suitable thickness.

To cure the adhesive layer, a chemical vulcanizing fluid is applied to the bonding area of the surface of the article to which the patch is to be bonded. For example, if curing the Tech International Chemical Cure Gum, the vulcanizing fluid Chemical Vulcanizing Fluid # 760 from Tech International may be utilized for the low temperature cure of the adhesive layer. The patch is then placed over the bonding area having the chemical vulcanizing fluid and stitched down on the surface to remove any air bubbles and ensure intimate contact between the adhesive layer and the entire bonding area. The cure may then take place at a temperature of between 18° C. and 26° C. for a time period of between 20 hours and 48 hours.

Without limitation, the electronics patch may be made of elastomeric material that includes, for example, natural rubber, styrene butadiene rubber, polybutadiene or combinations thereof The electronics patch may further include those materials known to one having ordinary skill in the art, such materials including, for example, one or more of the following: fillers such as carbon black and/or silica, accelerators, curing agents, stearic acid, zinc oxide and anti-degradants.

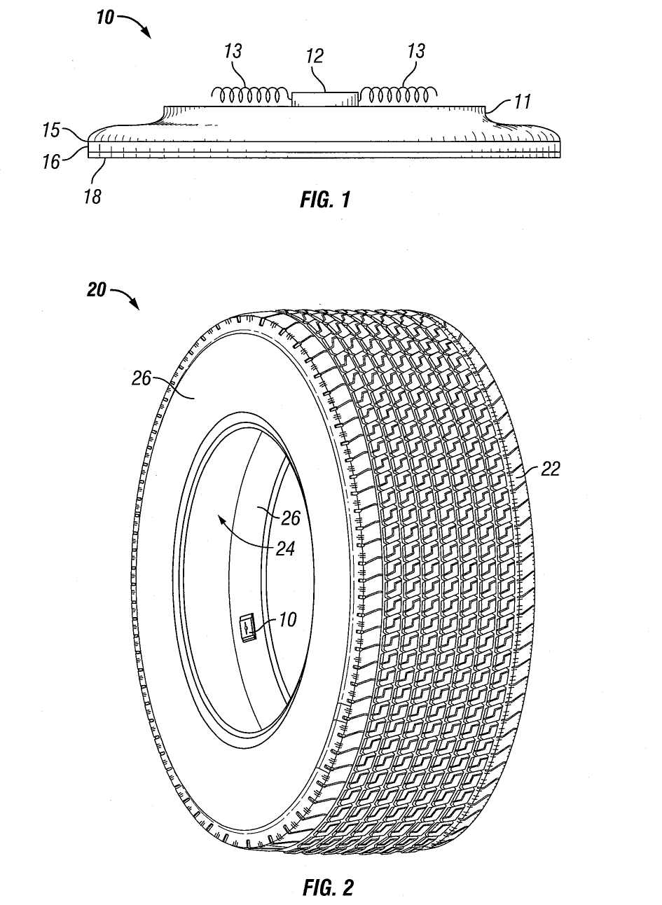

FIG. 1 is a cross sectional view of an exemplary electronics patch having a very thin adhesive layer for bonding the patch to an article. The illustrated electronics patch 10 comprises a patch body 11 having an electronics component 12 attached to the top surface of the patch body 11. In this embodiment, the electronics component 12 has two antennae 13 attached. Such electronic devices are well known in the industry. The electronics patch 10 includes a bottom surface 15 for bonding the electronic patch 10 to an article, such as a tire. The patch body 11 is composed of a cured rubber composition known by one having ordinary skill in the art.

An ultra thin adhesive layer 16 is applied to the bottom surface 15 of the electronics patch 10. The adhesive layer 16 is less than 0.3 mm thick and is covered with a protective plastic film 18. The plastic film 18 is removable and can be peeled off when the patch 10 is ready for application to an article. The adhesive layer 16 is composed of a material that can be cured at a selected temperature of between 18° C. and 26° C. over a curing time period of between 20 hours and 48 hours.

FIG. 2 is a perspective view of a tire having an electronics patch bonded to the tire. The illustrated tire 20 is an exemplary article to which an electronics patch 10, such as the one shown in FIG. 1, may be bonded by means of a thin adhesive layer 16. The tire 20 includes a crown section 22 having the tread for contacting the road and a pair of sidewall sections 26. The interior of the tire 20 is covered with an inner liner 24 composed of a rubber composition, the elastomeric portion being a majority of a butyl rubber as known to one having ordinary skill in the art. While this example shows the electronics patch bonded to the interior sidewall 26 of the tire 10, the invention is not so limited so that any suitable bonding location with the patch arranged in any suitable orientation would be within the contemplation of the present invention.

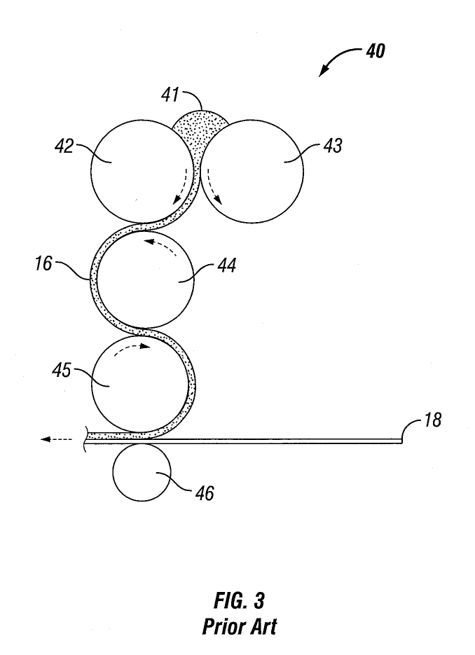

FIG. 3 is a schematic of a process for producing a very thin adhesive layer on a plastic film. While the adhesive layer can be stretched and pulled to form the thin layer of material that can be applied to the electronics patch, a suitable process for making thin sheets of the adhesive material is described in Japanese Patent Application 2002-254463. While this process is not part of the present invention, it does teach a suitable method for forming the thin layer of adhesive material and is hereby illustrated in FIG. 3.

The calendering process illustrated includes a side roller 43, a top roller 42, a middle roller 44 and a bottom roller 45. The rubber based adhesive material 41 is rolled in a three-step process, each step making the adhesive layer thinner. The first stage calenders the adhesive material between the top roller 42 and the side roller 43, the second stage calenders the adhesive material between the top roller 42 and the middle roller 44. The third stage calenders the adhesive material between the middle robber 44 and the bottom roller 45. Each stage further reduces the thickness of the rubber based adhesive material.

The adhesive layer 16 is transferred to the removable protective film 18 by passing the protective film 18 between the bottom roller 45 and the support roller 46. The adhesive layer 16 is then transferred to the surface of the protective film 18. The adhesive layer 16 with the protective film 18 can then be cut to the proper size and applied to the bottom surface 15 of the electronics patch 10.

The terms “comprising,” “including,” and “having,” as used in the claims and specification herein, shall be considered as indicating an open group that may include other elements not specified. The term “consisting essentially of,” as used in the claims and specification herein, shall be considered as indicating a partially open group that may include other elements not specified, so long as those other elements do not materially alter the basic and novel characteristics of the claimed invention. The terms “a,” “an,” and the singular forms of words shall be taken to include the plural form of the same words, such that the terms mean that one or more of something is provided. The terms “at least one” and “one or more” are used interchangeably. The term “one” or “single” shall be used to indicate that one and only one of something is intended. Similarly, other specific integer values, such as “two,” are used when a specific number of things is intended. The terms “preferably,” “preferred,” “prefer,” “optionally,” “may,” and similar terms are used to indicate that an item, condition or step being referred to is an optional (not required) feature of the invention. Ranges that are described as being “between a and b” are inclusive of the values for “a” and “b.”

It should be understood from the foregoing description that various modifications and changes may be made to the embodiments of the present invention without departing from its true spirit. The foregoing description is provided for the purpose of illustration only and should not be construed in a limiting sense. Only the language of the following claims should limit the scope of this invention.

What is claimed is:

1. An electronics patch, comprising:
a patch body composed of a cured rubber composition and having an electronics component mounted thereto, the patch body comprising a bottom surface for bonding the electronics patch to an article;
an adhesive layer composed of an uncured rubber composition and applied to the patch bottom surface, wherein the adhesive layer is no more than 0.3 mm thick and is curable at a selected temperature between 18° C. and 26° C. over a time period of between 20 hours and 48 hours;
a removable protective film applied to a bonding surface of the adhesive layer, wherein the protective film is removed prior to applying the electronics patch to the article.

2. The electronics patch of claim 1, wherein the uncured rubber composition of the adhesive layer comprises natural rubber in a majority amount and at least 10 phr of sulfur.

3. The electronics patch of claim 2, wherein the uncured rubber composition of the adhesive layer comprises at least 6 phr of sulfur.

4. The electronics patch of claim 1, wherein the adhesive layer is no more than 0.25 mm thick.

5. The electronics patch from claim 1, wherein the adhesive layer is between 0.1 and 0.25 mm thick.

6. The electronics patch of claim 1, wherein the adhesive layer is between 0.1 mm and 0.20 mm thick.

7. The electronics patch of claim 1, wherein the adhesive layer is no more than 0.2 mm thick.

8. A method for applying an electronics patch to a tire, the method comprising:
applying a vulcanizing agent to an interior surface of the tire;
applying the electronics patch over the vulcanizing agent, wherein the electronics patch comprises a patch body composed of a cured rubber composition and having an electronics component mounted thereto, the patch body comprising a bottom surface for bonding the electronics patch to an article; an adhesive layer composed of an uncured rubber composition and applied to the patch bottom surface, wherein the adhesive layer is no more than 0.3 mm thick and is curable at a selected temperature between 18° C. and 26° C. over a curing time period of between 20 hours and 48 hours; and a removable protective film applied to a bonding surface of the adhesive layer, wherein the protective film is removed prior to applying the electronics patch to the tire.

9. The method of claim 8, further comprising:
removing the protective film from the adhesive layer;
curing the adhesive layer at the selected temperature for the curing time period.

10. The method of claim 8, wherein the adhesive layer is between 0.1 and 0.25 mm thick.
